(19) United States
(12) Patent Application Publication
(10) Pub. No.: US 2018/0053788 A1
(43) Pub. Date: Feb. 22, 2018

(54) BACKPLANE FOR DISPLAY DEVICE AND METHOD OF MANUFACTURING THE SAME

(71) Applicant: SAMSUNG DISPLAY CO., LTD., Yongin-si (KR)

(72) Inventors: Bong-Won LEE, Seoul (KR); Jong-Hee PARK, Yongin-si (KR); Jin-Seock KIM, Seongnam-si (KR); Seung-Bae KANG, Suwon-si (KR)

(21) Appl. No.: 15/674,647

(22) Filed: Aug. 11, 2017

(30) Foreign Application Priority Data
Aug. 16, 2016 (KR) 10-2016-0103549

(51) Int. Cl. H01L 27/12; H01L 21/3213

(52) U.S. Cl. CPC H01L 27/124; H01L 27/1248; H01L 21/32134; G02F 1/134309; H01L 21/32138; H01L 27/1259; H01L 21/32135

(57) ABSTRACT

A backplane for a display device having a light emitting portion and a pad portion and a method of manufacturing the backplane for a display device, the backplane including a drain electrode in the light emitting portion on a substrate; a pad electrode in the pad portion on the substrate; a passivation layer in the light emitting portion to partially cover the drain electrode, the passivation layer exposing a portion of the drain electrode; a first pixel electrode in the light emitting portion on the passivation layer and the exposed drain electrode; and a second pixel electrode on the first pixel electrode, wherein: the second pixel electrode is formed of a material that is etchable by a first etching material, and the first pixel electrode is formed of a material that is not etchable by the first etching material.

### CROSS-REFERENCE TO RELATED APPLICATION

Korean Patent Application No. 10-2016-0103549, filed on Aug. 16, 2016, in the Korean Intellectual Property Office, and entitled: “Backplane for Display Device and Method of Manufacturing the Same,” is incorporated by reference herein in its entirety.

### BACKGROUND

### 1. Field

Embodiments relate to a backplane for display devices and a method of manufacturing the backplane for display devices.

### 2. Description of the Related Art

Recently, the importance of a flat panel display device having characteristics such as slim, light weight, low power consumption, etc. has been increasing. A liquid crystal display device and an organic light emitting display device among the flat panel display device may have excellent resolution, image quality, etc. Specifically, the organic light emitting display device may have characteristics such as high response speed, low power consumption, self-luminous, etc., which have drawn attention to the organic light emitting display device as a next generation display device.

### SUMMARY

Embodiments are directed to a backplane for display devices and a method of manufacturing the backplane for display devices.

The embodiments may be realized by providing a backplane for a display device having a light emitting portion and a pad portion, the backplane including a drain electrode in the light emitting portion on a substrate; a pad electrode in the pad portion on the substrate; a passivation layer in the light emitting portion to partially cover the drain electrode, the passivation layer exposing a portion of the drain electrode; a first pixel electrode in the light emitting portion on the passivation layer and the exposed drain electrode; and a second pixel electrode on the first pixel electrode, wherein: the second pixel electrode is formed of a material that is etchable by a first etching material, and the first pixel electrode is formed of a material that is not etchable by the first etching material.

The material of the first pixel electrode may be etchable by a second etching material, and the material of the second pixel electrode may not be etchable by the second etching material.

The second pixel electrode may have a shape that conforms to a shape of the first pixel electrode.

The pad electrode and the second pixel electrode may include materials that are susceptible to undergoing a galvanic reaction in cooperation with an electrolyte.

The pad electrode may include a first layer, a second layer, and a third layer which are sequentially stacked, and the second layer of the pad electrode and the second pixel electrode may include materials that are susceptible to undergoing a galvanic reaction in cooperation with an electrolyte.

The first pixel electrode and the third layer of the pad electrode may include a same material.

The second pixel electrode may include a first layer, a second layer, and a third layer which are sequentially stacked, and the first layer and the third layer may protect a bottom surface and a top surface of the second layer, respectively.

The second pixel electrode may include a first layer and a second layer which are sequentially stacked, and the first pixel electrode and the second layer may protect a bottom surface and a top surface of the first layer, respectively.

The drain electrode and the pad electrode may be disposed at a same level on the substrate.

The embodiments may be realized by providing a method of manufacturing a backplane for a display device having a light emitting portion and a pad portion, the method including forming a drain electrode on a substrate in the light emitting portion; forming a pad electrode on the substrate in the pad portion; forming a passivation layer in the light emitting portion to partially cover the drain electrode, the passivation layer exposing a portion of the drain electrode; forming a first pixel electrode layer on the passivation layer, the exposed drain electrode, and the pad electrode; forming a second pixel electrode layer on the first pixel electrode layer; etching the second pixel electrode layer with a first etching material to form a second pixel electrode; and etching the first pixel electrode layer with a second etching material to form a first pixel electrode, wherein the first pixel electrode layer is not etched by the first etching material during the etching of the second pixel electrode layer.

Etching the second pixel electrode layer may include performing a wet-etching method.

The second pixel electrode layer may not be etched by the second etching material during the etching of the first pixel electrode layer.

Etching the first pixel electrode layer may include performing a dry-etching method.

The pad electrode and the second pixel electrode layer may include materials that are susceptible to undergoing a galvanic reaction in cooperation with an electrolyte.

The first pixel electrode layer may cover a top surface and a sidewall of the pad electrode.

The pad electrode may include a first layer, a second layer, and a third layer which are sequentially stacked, and the second layer of the pad electrode and the second pixel electrode layer may include materials that are susceptible to undergoing a galvanic reaction in cooperation with an electrolyte.

The first pixel electrode layer may cover a sidewall of the pad electrode.

The first pixel electrode layer and the third layer of the pad electrode may include a same material.

The drain electrode and the pad electrode may be simultaneously formed.

The method may further include forming a photoresist pattern corresponding to the second pixel electrode on the second pixel electrode layer prior to etching the second pixel electrode layer; and removing the photoresist pattern after etching the first pixel electrode layer.

### BRIEF DESCRIPTION OF THE DRAWINGS

Features will be apparent to those of skill in the art by describing in detail exemplary embodiments with reference to the attached drawings in which:

FIG. 1 illustrates a plan view of a backplane for a display device according to an exemplary embodiment.

FIG. 2 illustrates a plan view of a backplane for a display device according to an exemplary embodiment.

FIG. 3 illustrates a cross-sectional view of a backplane for a display device according to an exemplary embodiment.

FIGS. 4, 5, 6, 7, 8, 9, 10, 11, and 12 illustrate cross-sectional views of stages in a method of manufacturing a backplane for a display device according to an exemplary embodiment.

FIG. 13 illustrates a cross-sectional view of a backplane for a display device according to another exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or subs element trate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, a backplane for a display device and a method of manufacturing the backplane for the display device in accordance with exemplary embodiments will be explained in detail with reference to the accompanying drawings.

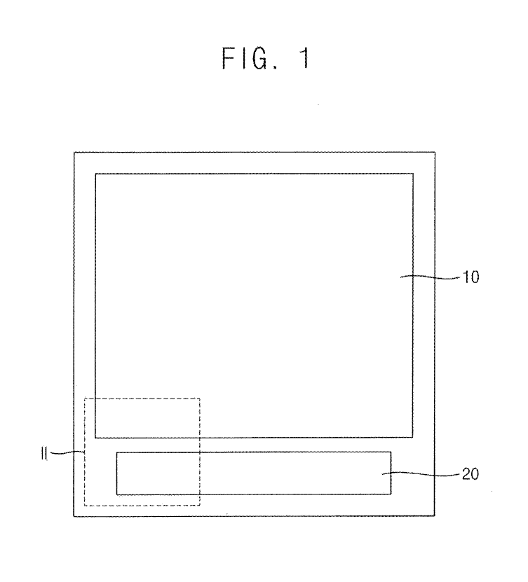

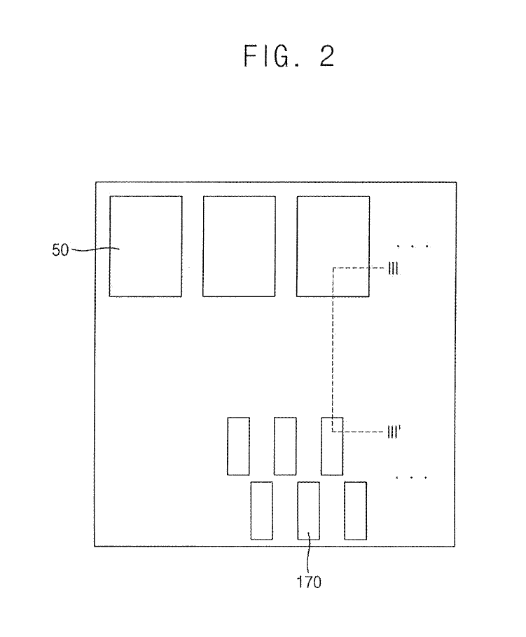

FIG. 1 illustrates a plan view of a backplane for a display device according to an exemplary embodiment. FIG. 2 illustrates a plan view of a backplane for a display device according to an exemplary embodiment. For example, FIG. 2 may be a plan view enlarging a portion II in FIG. 1.

Referring to FIGS. 1 and 2, a backplane for a display device according to an exemplary embodiment may include a light emitting portion 10 and a peripheral portion surrounding the light emitting portion 10. The peripheral portion may include a pad portion 20.

A plurality of pixels 50 (arranged as a substantial matrix structure between a scan line for transmitting scan signals, a data line for transmitting data signals, and a driving voltage line for transmitting driving voltage) may be formed in the light emitting portion 10. Each of the pixels 50 may include at least one thin film transistor for controlling the pixel 50.

A plurality of pad electrodes 170 (connected to the scan line and the data line to transmit signals) may be formed in the pad portion 20.

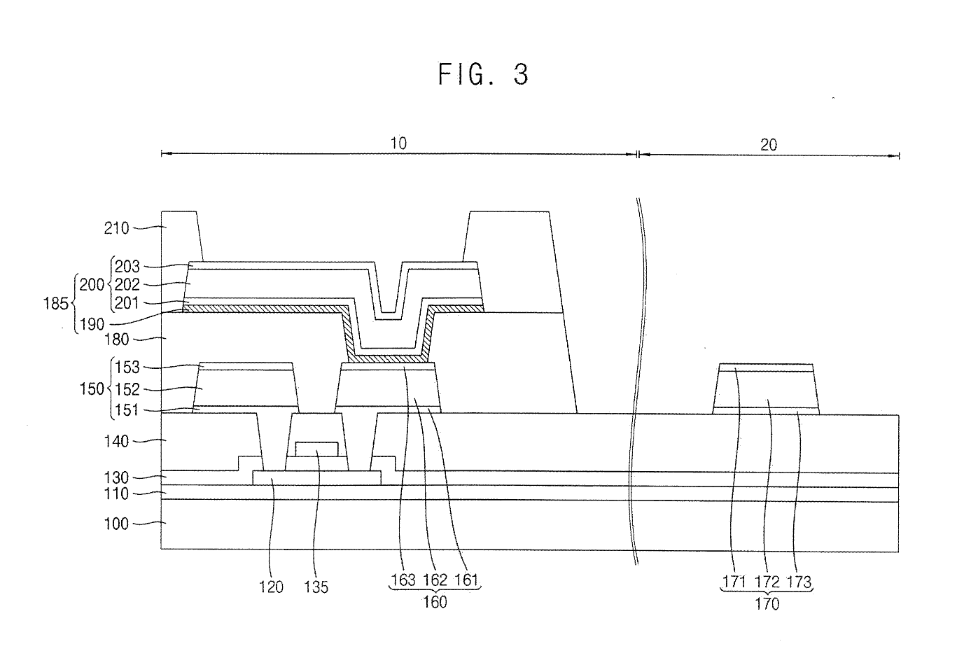

FIG. 3 illustrates a cross-sectional view illustrating a backplane for a display device according to an exemplary embodiment of the present invention. FIG. 3 may be a cross-sectional view cut along a line of the backplane for the display device in FIG. 2.

Referring to FIG. 3, the backplane for the display device according to an exemplary embodiment may include a drain electrode 160 disposed in the light emitting portion 10 on the substrate 100, a pad electrode 170 disposed in the pad portion 20 on the substrate 100, a passivation layer 180 disposed in the light emitting portion 10 to cover (e.g., at least partially cover) the drain electrode 160 and exposing a portion of the drain electrode 160, a first pixel electrode 190 disposed in the light emitting portion 10 on the passivation layer 180 and the exposed drain electrode 160, and a second pixel electrode 200 disposed on the first pixel electrode 190.

A buffer layer 110 may be disposed on the substrate 100. The buffer layer 110 may extend from the light emitting portion 10 to the pad portion 20. The buffer layer 110 may help substantially prevent the diffusion of impurities, and may help control a heat transfer rate in a crystallization process during the formation of an active pattern 120. Further, the buffer layer 110 may improve the flatness of a surface of the substrate 100. In an implementation, the buffer layer 110 may be omitted.

A thin film transistor (TFT) may be disposed on the buffer layer 110. In an implementation, as illustrated in FIG. 3, one thin film transistor may be included. In an implementation, a plurality of thin film transistors may be disposed on the buffer layer 110. The thin film transistor may include the active pattern 120, a gate electrode 135, a source electrode 150, and the drain electrode 160. The thin film transistor may transmit a driving signal for driving a pixel to a pixel electrode 185.

The active pattern 120 may be disposed on the buffer layer 110. The active pattern 120 may be located in the light emitting portion 10.

The gate electrode 135 may be disposed on the active pattern 120. A gate insulation layer 130 may be disposed between the active pattern 120 and the gate electrode 135. The gate insulation layer 130 may insulate the gate electrode 135 from the active pattern 120. The gate electrode 135 may overlap a center portion of the active pattern 120. The gate insulation layer 130 may be extended from the light emitting portion 10 to the pad portion 20.

The source electrode 150 and the drain electrode 160 may be disposed on the gate electrode 135. An insulation interlayer 140 may be disposed between the gate electrode 135 and the source/drain electrodes 150 and 160. The insulation interlayer 140 may insulate the source/drain electrodes 150 and 160 from the gate electrode 135. The insulation interlayer 140 may be extended from the light emitting portion 10 to the pad portion 20.

The source electrode 150 and the drain electrode 160 may be electrically connected to the active pattern 120. For example, contact holes may be formed in the gate insulation layer 130 and the insulation interlayer 140, and the contact holes may expose opposing sides of the active pattern 120, respectively. The source electrode 150 and the drain electrode 160 may be in contact with the active patterns 120 through the contact holes, respectively.

In an implementation, the source electrode 150 may include a first layer 151, a second layer 152, and a third layer 153 which are sequentially stacked. In an implementation, the drain electrode 160 may include a first layer 161, a second layer 162, and a third layer 163 which are sequentially stacked. The second layers 152 and 162 of the source/drain electrodes 150 and 160 may function as main electrode layers. The first layers 151 and 161 and the third layers 153 and 163 of the source/drain electrodes 150 and 160 may function as auxiliary electrode layers that protect bottom surfaces and top surfaces of the second layers 152 and 162, respectively. In an implementation, the source/drain electrodes 150 and 160 may be formed of a triple-layered structure including titanium (Ti)/aluminum (Al)/titanium (Ti), respectively.

The pad electrode 170 may be disposed on the substrate 100. The pad electrode 170 may be located in the pad portion 20. In an implementation, the pad electrode 170 may be disposed at substantially the same level with the source/drain electrodes 150 and 160 on the substrate 100 (e.g., a bottom of the pad electrode 170 may be coplanar with a bottom of the source electrode 150 and/or the drain electrode 160). For example, the pad electrode 170 may be disposed on the insulation interlayer 140 like the source/drain electrodes 150 and 160.

In an implementation, the pad electrode 170 may include a material that causes or is susceptible to undergoing a galvanic reaction with the second pixel electrode 200 in cooperation with an electrolyte. If the galvanic reaction were to occur, the pad electrode 170 could be damaged. A method for preventing the undesirable galvanic reaction will be described in detail in a method of manufacturing a backplane for a display device below.

In an implementation, the pad electrode 170 may include a first layer 171, a second layer 172, and a third layer 173 that are sequentially stacked. The second layer 172 of the pad electrode 170 may function as a main electrode layer. The first layer 171 and the third layer 173 of the pad electrode 170 may function as auxiliary electrode layers which protect a bottom surface and a top surface of the second layer 172, respectively. In an implementation, the pad electrode 170 may be formed of a triple-layered structure including titanium (Ti)/aluminum (Al)/titanium (Ti).

In an implementation, the second layer 172 of the pad electrode 170 may include a material that causes or is susceptible to undergoing a galvanic reaction with the second pixel electrode 200 in cooperation with an electrolyte. If the galvanic reaction were to occur, the second layer 172 of the pad electrode 170 could be damaged. A method for preventing the galvanic reaction will be described in detail in a method of manufacturing a backplane for a display device below.

In an implementation, the third layer 173 of the pad electrode 170 may include a material substantially the same as that of the first pixel electrode 190. In an implementation, the third layer 173 of the pad electrode 170 and the first pixel electrode 190 may each include titanium (Ti).

The pixel electrode 185 may be disposed on the source/drain electrodes 150 and 160. The passivation layer 180 may be disposed between the source/drain electrodes 150 and 160 and the pixel electrode 185. For example, a part of the passivation layer 180 may be between the source electrode 150 and the pixel electrode 185 (e.g., and the pixel electrode 185 may be electrically connected to the drain electrode 160). The passivation layer 180 may insulate the pixel electrode 185 from at least one of the source/drain electrodes 150 and 160. The passivation layer 180 may be selectively located in the light emitting portion 10.

The pixel electrode 185 may be electrically connected to the drain electrode 160. For example, a via hole may be formed in the passivation layer 180, and the via hole may expose a portion of the drain electrode 160. The pixel electrode 185 may be in contact with the drain electrode 160 through the via hole.

The pixel electrode 185 may include the first pixel electrode 190 and the second pixel electrode 200. The first pixel electrode 190 may be disposed in the light emitting portion 10 on the passivation layer 180 and the exposed drain electrode 160. The second pixel electrode 200 may be disposed on the first pixel electrode 190.

Etching characteristics of the first pixel electrode 190 and the second pixel electrode 200 may be different from each other. In an implementation, the second pixel electrode 200 may be etched or etchable by a first etching material, and the first pixel electrode 190 may be etched or etchable by a second etching material. For example, the first pixel electrode 190 may not be etched or etchable by the first etching material, and the second pixel electrode 200 may not be etched or etchable by the second etching material. For example, the first pixel electrode 190 may be resistant to etching by the first etching material and the first pixel electrode 190 may be etchable by the second etching material. For example, the second pixel electrode 200 may be resistant to etching by the second etching material and the second pixel electrode 200 may be etchable by the first etching material.

In an implementation, the second pixel electrode 200 may be formed to conform to a shape of the first pixel electrode 190. For example, the first pixel electrode 190 may have a shape corresponding to a profile of a top surface of the passivation layer 180, a sidewall of the passivation layer 180 in which the via hole is formed, a top surface of the exposed drain electrode 160, and the second pixel electrode 200 may be formed to conform to the shape of the first pixel electrode 190. Therefore, the first pixel electrode 190 and the second pixel electrode 200 may have shapes corresponding to each other.

In an exemplary embodiment, the second pixel electrode 200 may include a first layer 201, a second layer 202, and a third layer 20 that are sequentially stacked. The second layer 202 of the second pixel electrode 200 may function as a main electrode layer. The first layer 201 and the third layer 203 of the second pixel electrode 200 may function as auxiliary electrode layers that protect a bottom surface and a top surface of the second layer 202, respectively. In an implementation, the second pixel electrode 200 may be formed of a triple-layered structure including indium-tin-oxide (ITO)/silver (Ag)/indium-tin-oxide (ITO).

A pixel defining layer 210 may be disposed on the passivation layer 180. The pixel defining layer 210 may partially cover the pixel electrode 185. For example, the pixel defining layer 210 may cover an edge portion of the pixel electrode 185, and may expose a center portion of the pixel electrode 185. The pixel defining layer 210 may be selectively located in the light emitting portion 10.

The backplane for the display device according to an exemplary embodiment may be applied to various display devices. In an implementation, when an organic light emitting layer is formed on the exposed pixel electrode 185, and an opposing electrode facing the pixel electrode 185 with respect to the organic light emitting layer is formed, the backplane for the display device according to an exemplary embodiment may be used as a backplane for an organic light emitting display device. In an implementation, when a liquid crystal layer is formed on the exposed pixel electrode 185, and a common electrode facing the pixel electrode 185 with respect to the liquid crystal layer is formed, the backplane for the display device according to an exemplary may be used as a backplane for a liquid crystal display device. In an implementation, the backplane for the display device according to an exemplary embodiment may be used for various display devices.

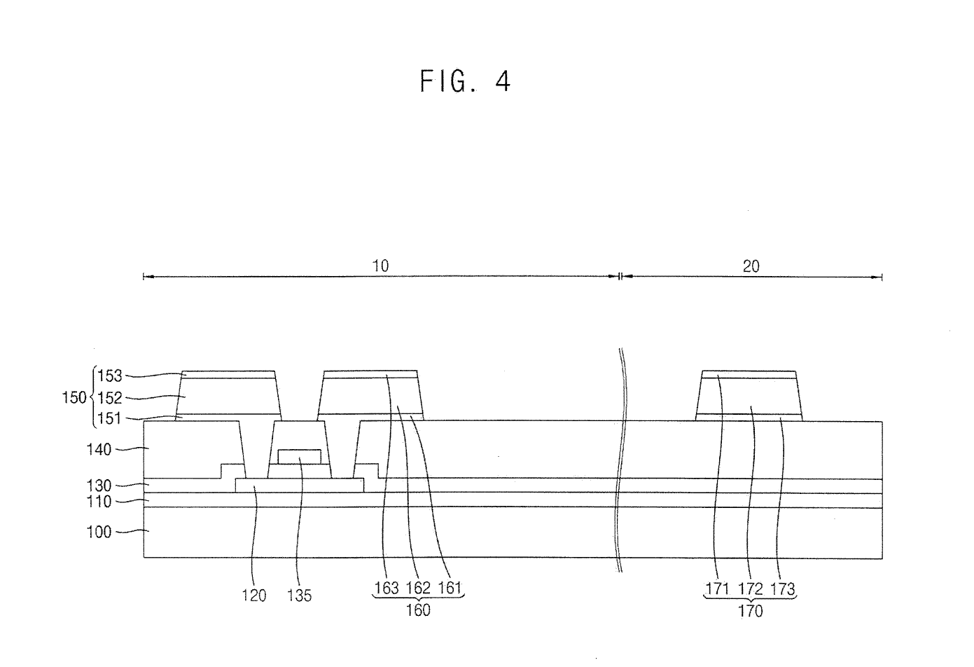

FIGS. 4, 5, 6, 7, 8, 9, 10, 11, and 12 illustrate cross-sectional views of stages in a method of manufacturing a backplane for a display device according to an exemplary embodiment.

Referring to FIG. 4, the substrate 100 may include the light emitting portion 10 and the pad portion 20. The buffer layer 110, the gate insulation layer 130, and the insulation interlayer 140 may be sequentially formed on the substrate 100. The active pattern 120, the gate electrode 135, and the source/drain electrodes 150 and 160 may be sequentially formed in the light emitting portion 10 on the substrate 100. The pad electrode 170 may be formed in the pad portion 20 on the substrate 100.

The buffer layer 110 may be formed on the substrate 100, and may extend from the light emitting portion 10 to the pad portion 20. For example, the buffer layer 110 may be formed of silicon oxide or silicon nitride by using various deposition methods such as a plasma enhanced chemical vapor deposition (PECVD), an atmospheric pressure chemical vapor deposition (APCVD), a low pressure chemical vapor deposition (LPCVD), or the like. In an implementation, the buffer layer 110 may not be formed.

The active pattern 120 may be formed in the light emitting portion 10 on the buffer layer 110. For example, a layer including silicon or an oxide semiconductor may be formed on a substantially entire surface of the buffer layer 110, and then the layer may be patterned to form the active pattern 120. When the active pattern 120 is formed of the silicon, an amorphous silicon layer may be formed on a substantially entire surface of the buffer layer 110, and then the amorphous silicon layer may be crystallized to form a polycrystalline silicon layer. Then, the polycrystalline silicon layer may be patterned, and impurities may be doped at opposing sides of the patterned polycrystalline silicon layer to form the active pattern 120 including a source region, a drain region, and a channel region therebetween.

The gate insulation layer 130 may be formed on the buffer layer 110 to cover the active pattern 120. The gate insulation layer 130 may extend from the light emitting portion 10 to the pad portion 20. For example, the gate insulation layer 130 may be formed of silicon oxide, silicon nitride, or the like.

The gate electrode 135 may be formed in the light emitting portion 10 on the gate insulation layer 130. The gate electrode may overlap the active pattern 120. For example, the gate electrode 135 may be formed of a metal, an alloy thereof, a nitride thereof, a conductive oxide thereof, a transparent conductive oxide, or the like.

The insulation interlayer 140 may be formed on the gate insulation layer 130 to cover the gate electrode 135. The insulation interlayer 140 may extend from the light emitting portion 10 to the pad portion 20. For example, the insulation interlayer 140 may be formed of silicon oxide, silicon nitride, or the like.

The contact holes may be formed in the gate insulation layer 130 and the insulation interlayer 140. The contact holes may expose portions of the active pattern 120. For example, the contact holes may expose opposing sides of the active pattern 120, respectively.

The source electrode 150 and the drain electrode 160 may be formed in the light emitting portion 10 on the insulation interlayer 140. The source electrode 150 and the drain electrode 160 may be in contact with the active pattern 120 through the contact holes, respectively. In an implementation, the source electrode 150 and the drain electrode 160 may be formed of a metal, an alloy thereof, a nitride thereof, a conductive oxide thereof, a transparent conductive oxide, or the like.

The pad electrode 170 may be formed in the pad portion 20 on the substrate 100. In an implementation, the pad electrode 170 may be formed of a metal, an alloy thereof, a nitride thereof, a conductive oxide thereof, a transparent conductive oxide, or the like. In an implementation, the pad electrode 170 may be disposed at substantially the same level with the source/drain electrodes 150 and 160 on the substrate 100. In this case, the pad electrode 170 may be formed on the insulation interlayer 140.

In an implementation, the source electrode 150, the drain electrode 160, and the pad electrode 170 may be substantially simultaneously formed. For example, a conductive layer extending from the light emitting portion 10 to the pad portion 20 may be formed on the insulation interlayer 140, and then the conductive layer may be patterned to simultaneously form the source electrode 150, the drain electrode 160, and the pad electrode 170.

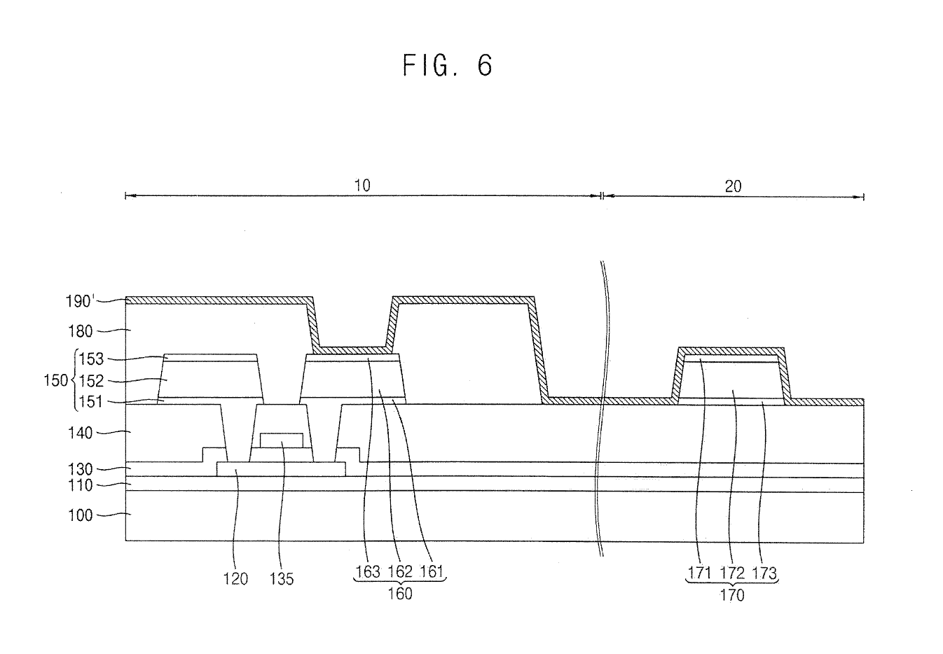

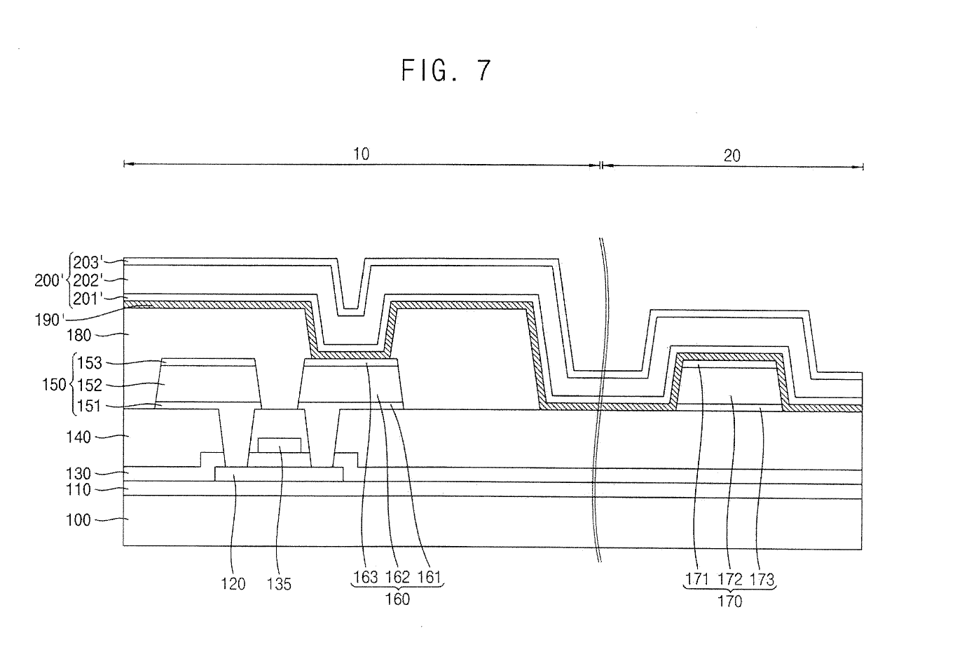

In an implementation, the pad electrode 170 may include a material that causes or is susceptible to undergoing a galvanic reaction with a second pixel electrode layer 200′ (see FIG. 7) in cooperation with an electrolyte. For example, the pad electrode 170 may include aluminum (Al), the second pixel electrode layer 200′ may include silver (Ag), and aluminum (Al) and silver (Ag) may cause or undergo the galvanic reaction in cooperation with an electrolyte. If the galvanic reaction were to occur, the pad electrode 170 could be damaged. In an effort to help prevent the galvanic reaction, a method of manufacturing a backplane for a display device according to an exemplary embodiment may include the formation of the first pixel electrode layer 190′ (see FIG. 6) as described below.

In an implementation, the source electrode 150 may include the first layer 151, the second layer 152, and the third layer 153 which are sequentially stacked, the drain electrode 160 may include the first layer 161, the second layer 162, and the third layer 163 which are sequentially stacked, and the pad electrode 170 may include the first layer 171, the second layer 172, and the third layer 173 which are sequentially stacked. For example, a first sub-conductive layer, a second sub-conductive layer, and a third sub-conductive layer, which extend from the light emitting portion 10 to the pad portion 20 and are sequentially stacked, may be formed on the insulation interlayer 140. Then the first to third sub-conductive layers may be patterned to form the source electrode 150, the drain electrode 160, and the pad electrode 170. For example, the first to third sub-conductive layers may include titanium (Ti), aluminum (Al), and titanium (Ti), respectively. In an implementation, the source electrode 150, the drain electrode 160, and the pad electrode 170 may be formed a triple-layered structure including Ti/Al/Ti, respectively.

In an implementation, the second layer 172 of the pad electrode 170 may include a material that causes or is susceptible to undergoing a galvanic reaction with the second pixel electrode layer 200′ in cooperation with an electrolyte. For example, the second layer 172 of the pad electrode 170 may include aluminum (Al), the second pixel electrode layer 200′ may include silver (Ag), and aluminum (Al) and silver (Ag) may cause the galvanic reaction in cooperation with an electrolyte. If the galvanic reaction were to occur, the second layer 172 of the pad electrode 170 could be damaged. To prevent the galvanic reaction, a method of manufacturing a backplane for a display device according to an exemplary embodiment may include the formation of the first pixel electrode layer 190′ as described below.

In an implementation, the third layer 173 of the pad electrode 170 may include a material that is substantially the same as that of the first pixel electrode layer 190′ that will be described below. In an implementation, the third layer 173 of the pad electrode 170 and the first pixel electrode layer 190′ may each include titanium (Ti).

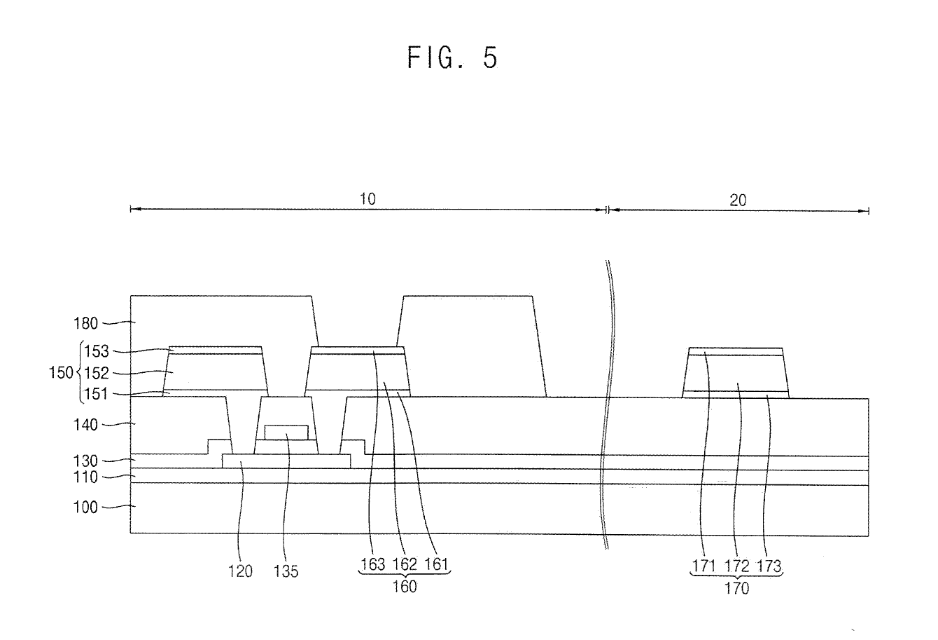

Referring to FIG. 5, the passivation layer 180 may be formed in the light emitting portion 10 on the insulation interlayer 140 to cover the source electrode 150 and the drain electrode 160.

The via hole may be formed in the passivation layer 180. The via hole may expose a portion of the drain electrode 160. For example, the via hole may expose a top surface of the drain electrode 160. The passivation layer 180 may be formed of an organic material. In an implementation, the passivation layer 180 may be formed of, e.g., a polyimide based resin, a photoresist, an acrylic based resin, a polyamide based resin, a siloxane based resin, or the like. These may be used alone or a combination thereof.

The passivation layer 180 may be selectively formed in the light emitting portion 10, and may not be extended to the pad portion 20. If the passivation layer 180 including an organic material were to extend to the pad portion 20, and moisture were to flow into a side portion of a backplane for a display device from outside, the moisture could move from the pad portion 20 to the light emitting portion 10 through the passivation layer 180, thereby degrading pixels. In an effort to help prevent the degradation of the pixel, the passivation layer 180 may not be disposed in the pad portion 20, so that a top surface and a sidewall of the pad electrode 170 may be exposed.

In some methods of manufacturing a backplane for a display device, to form a pixel electrode on a passivation layer, a pixel electrode layer (which extends from a light emitting portion to a pad portion) may be formed on the passivation layer and an insulation interlayer, and then the pixel electrode layer may be patterned by an etching process using an etchant to form the pixel electrode. However, the pixel electrode layer may be in contact with the exposed top surface and sidewall of the pad electrode. Further, when a standard reduction potential gap between metals included in the pixel electrode layer and the pad electrode is relatively large (e.g., the pixel electrode layer includes silver (Ag), and the pad electrode includes aluminum (Al)), a galvanic reaction may occur between the pixel electrode and the pad electrode in cooperation with an electrolyte thereby corroding the pad electrode. To help prevent the corrosion of the pad electrode, a method of manufacturing a backplane for a display device according to an exemplary embodiment may include the formation of the first pixel electrode layer 190′.

Referring to FIGS. 6 to 11, the first pixel electrode layer 190′ and the second pixel electrode layer 200′ may be sequentially formed, and then the second pixel electrode layer 200′ and the first pixel electrode layer 190′ may be sequentially patterned to form the pixel electrode 185 including the first pixel electrode 190 and the second pixel electrode 200.

Referring to FIG. 6, the first pixel electrode layer 190′ may be formed on the passivation layer 180 and the insulation interlayer 140. The first pixel electrode layer 190′ may extend from the light emitting portion 10 to the pad portion 20. The first pixel electrode layer 190′ may be in contact with the drain electrode 160 exposed by the via hole in the passivation layer, and may cover the pad electrode 170. For example, the first pixel electrode layer 190′ may cover a top surface and a sidewall of the pad electrode 170. Therefore, when the second pixel electrode layer 200′ (extended from the light emitting portion 10 to the pad portion 20) is formed, and the second pixel electrode layer 200′ is etched by a first etching material, the first pixel electrode layer 190′ may block the first etching material from contacting the pad electrode 170.

The first pixel electrode layer 190′ may be formed along a profile of the exposed drain electrode 160, the insulation interlayer 140, and the pad electrode 170. The first pixel electrode layer 190′ may have a substantially uniform thickness. For example, the first pixel electrode layer 190′ may be formed by sputtering, chemical vapor deposition, physical vapor deposition, or the like.

The first pixel electrode layer 190′ may include a material that is not etched by the first etching material for etching the second pixel electrode layer 200′. For example, when the second pixel electrode layer 200′ includes silver (Ag) and/or indium-tin-oxide (ITO), the first etching material may be a material for etching silver (Ag) and/or indium-tin-oxide (ITO), and the first pixel electrode layer 190′ may include titanium (Ti), chromium (Cr), nickel (Ni), or the like, which are not etched by the first etching material.

Referring to FIG. 7, the second pixel electrode layer 200′ may be formed on the first pixel electrode layer 190′. The second pixel electrode layer 200′ may extend from the light emitting portion 10 to the pad portion 20. The second pixel electrode layer 200′ may be formed along a profile of the first pixel electrode layer 190′. The second pixel electrode layer 200′ may have a substantially uniform thickness. For example, the second pixel electrode layer 200′ may be formed by sputtering, chemical vapor deposition, physical vapor deposition, or the like.

In an implementation, a first layer 201′, a second layer 202′, and a third layer 203′ may be sequentially stacked to form the second pixel electrode layer 200′. For example, the first layer 201′ and the third layer 203′ may include indium-tin-oxide (ITO), and the second layer 202′ may include silver (Ag).

In an implementation, the second pixel electrode layer 200′ may include a material that causes or is susceptible to undergoing a galvanic reaction with the pad electrode 170 in cooperation with an electrolyte. The first pixel electrode layer 190′ may be formed between the pad electrode 170 and the second pixel electrode layer 200′ as described above. Thus, damage to the pad electrode 170 may be prevented (e.g., the galvanic reaction may be prevented from occurring). In an implementation, when the pad electrode 170 includes the first to third layers 171, 172, and 173, the second pixel electrode layer 200′ includes a material that causes or is susceptible to undergoing a galvanic reaction with the second layer 172 of the pad electrode 170 in cooperation with an electrolyte, the first pixel electrode layer 190′ may be formed between the second layer 172 of the pad electrode 170 and the second pixel electrode layer 200′ as described above. Thus. damage of the second layer 172 of the pad electrode 170 may be prevented.

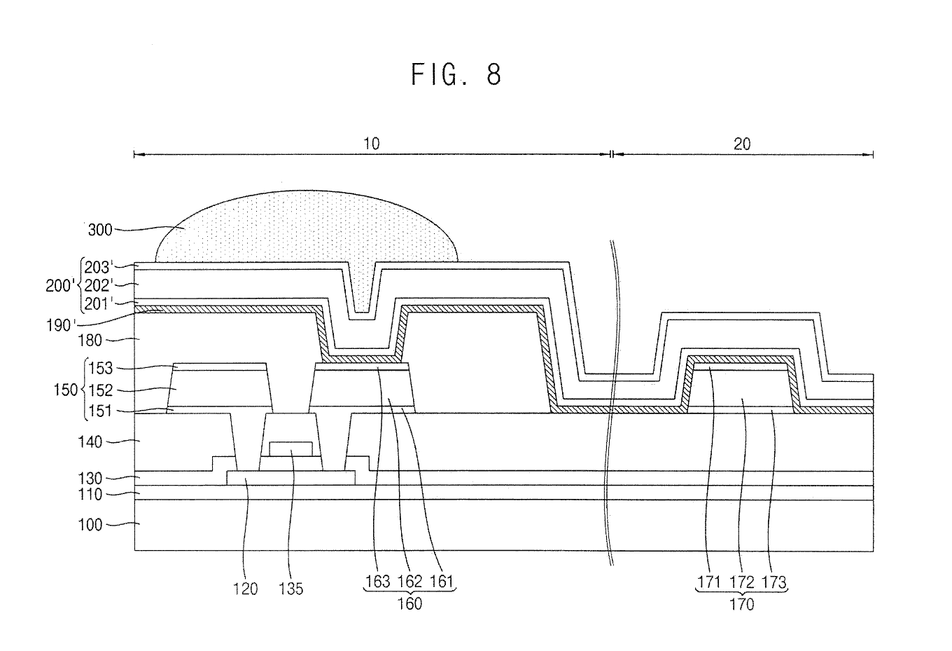

Referring to FIG. 8, a photoresist pattern 300 may be formed on the second pixel electrode layer 200′. The photoresist pattern 300 may correspond to a region in which the pixel electrode 185 is formed. For example, a photoresist layer extending from the light emitting portion 10 to the pad portion 20 may be formed on the second pixel electrode layer 200′, and then the photoresist layer may be exposed and developed by using a mask to form the photoresist pattern 300.

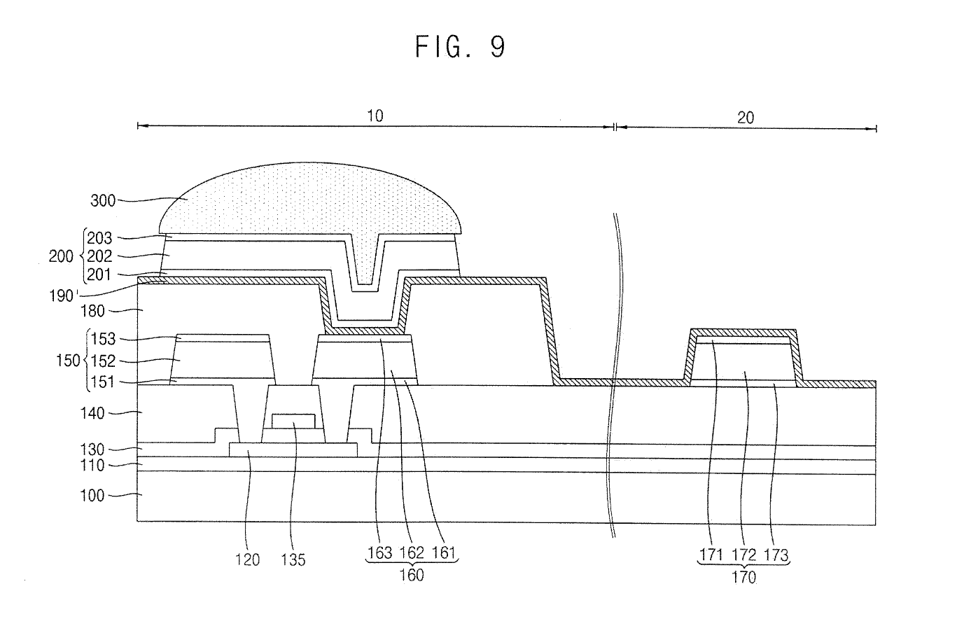

Referring to FIG. 9, the second pixel electrode layer 200′ may be patterned to form the second pixel electrode 200. The second pixel electrode layer 200′ may be etched by the aforementioned first etching material. Hereinafter, a step of etching the second pixel electrode layer 200′ by using the first etching material will be addressed as a first etching step.

In an implementation, the first etching step may be a wet-etching step. For example, the second pixel electrode layer 200′ may be etched by an etchant including the first etching material, so that the second pixel electrode layer 200′ outside a region on which the photoresist pattern 300 covers may be removed. As described above, when the second pixel electrode layer 200′ is formed of a triple-layered structure including ITO/Ag/ITO, the triple-layered structure may be etched by the first etching material at substantially the same time. In this case, the first pixel electrode layer 190′ disposed under the second pixel electrode layer 200′ may not be etched by the first etching material.

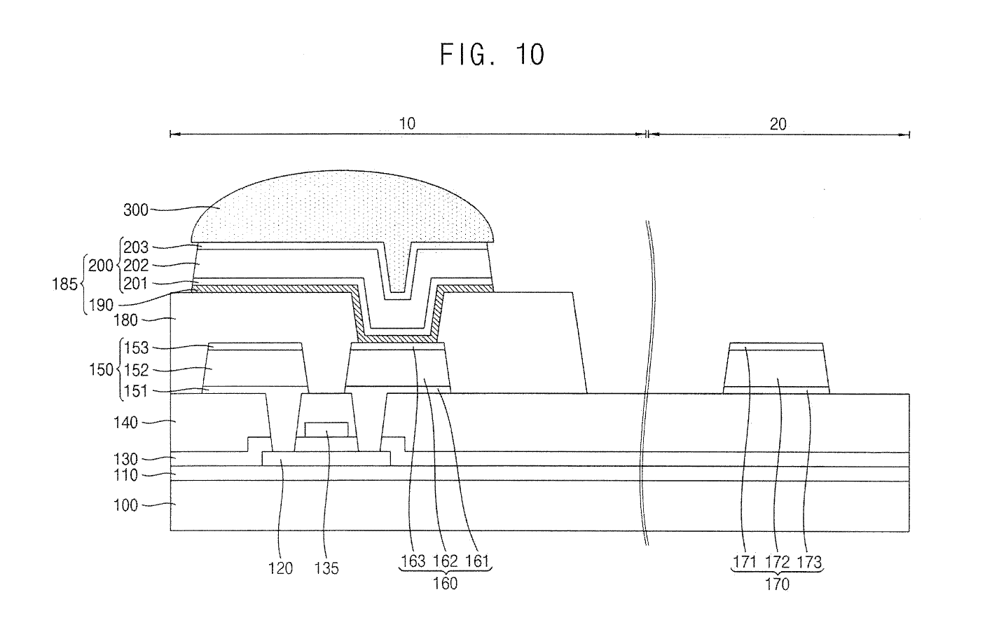

Referring to FIG. 10, the first pixel electrode layer 190′ may be patterned to form the first pixel electrode 190. The first pixel electrode layer 190′ may be etched by a second etching material that is different from the first etching material. Hereinafter, a step of etching the first pixel electrode layer 190′ by using the second etching material will be addressed as a second etching step.

In an implementation, the second etching step may be a dry-etching step. For example, the first pixel electrode layer 190′ may be etched by an etching gas including the second etching material, so that the first pixel electrode layer 190′ outside a region on which the second pixel electrode 200 and the photoresist pattern 300 cover may be removed.

In an implementation, the second etching material may etch the first pixel electrode layer 190′ only. For example, the second pixel electrode 200 may not be etched by the second etching material. Further, the pad electrode 170 may not be etched in the second etching step. In an implementation, the pad electrode 170 under the first pixel electrode layer 190′ may include a material (e.g., a material substantially the same as that of the first pixel electrode layer 190′) etched by the second etching material. However, the pad electrode 170 may not be etched by the second etching material or etching of the pad electrode 170 by the second etching material may be minimized by controlling the conditions of the etching process of the second etching step.

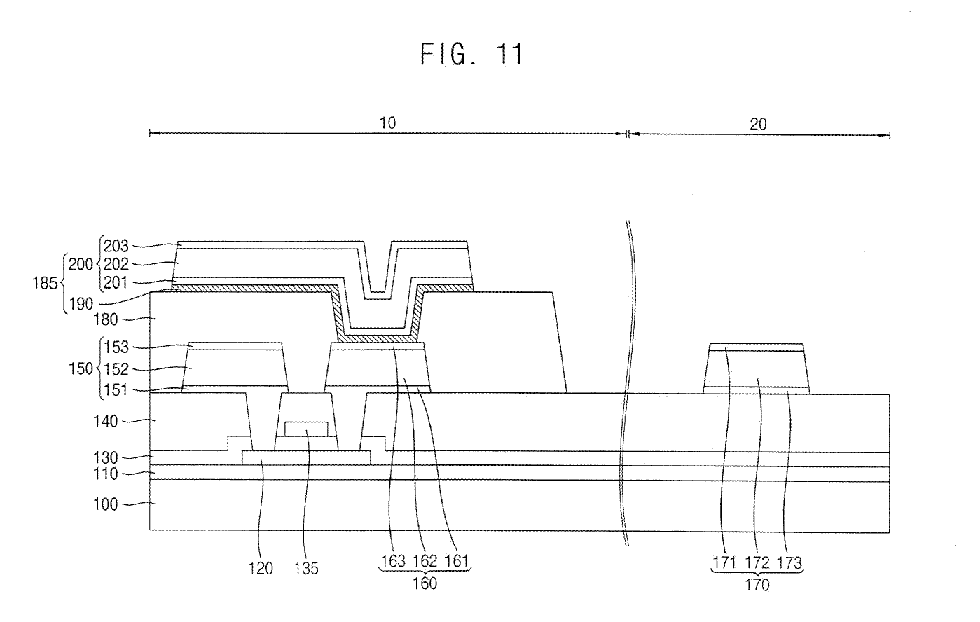

Referring to FIG. 11, the photoresist pattern 300 may be removed after the second etching step.

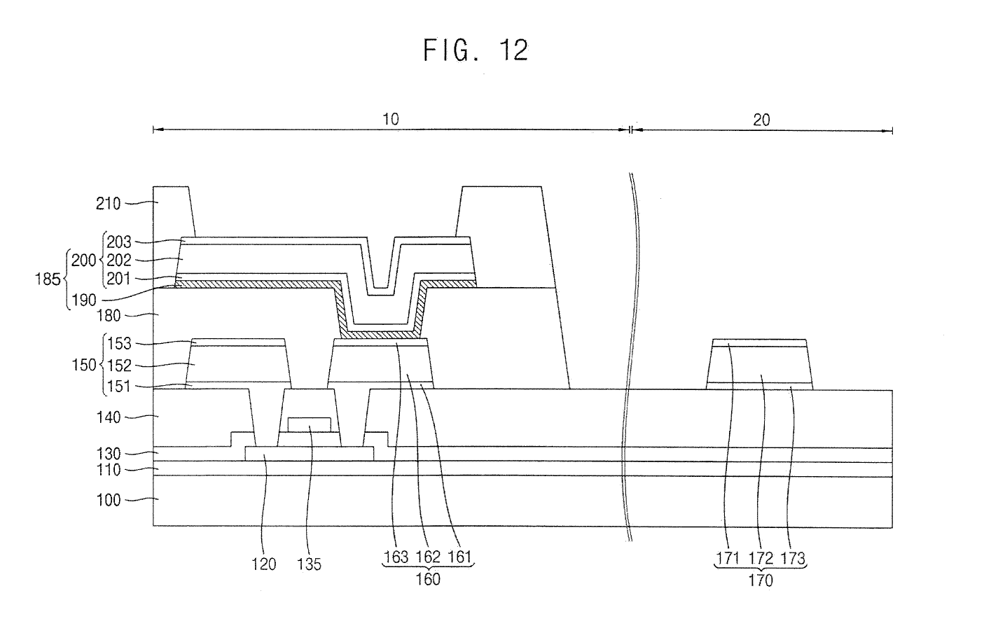

Referring to FIG. 12, the pixel defining layer 210 may be formed in the light emitting portion 10 on the passivation layer 180 to cover the pixel electrode 185.

An opening may be formed in the pixel defining layer 210 to expose a portion of the pixel electrode 185. For example, the opening may expose the center portion of the pixel electrode 185. The pixel defining layer 210 may be formed of an organic material. For example, the pixel defining layer 210 may be formed of a polyimide based resin, a photoresist, an acrylic based resin, a polyamide based resin, a siloxane based resin, or the like. These may be used alone or a combination thereof.

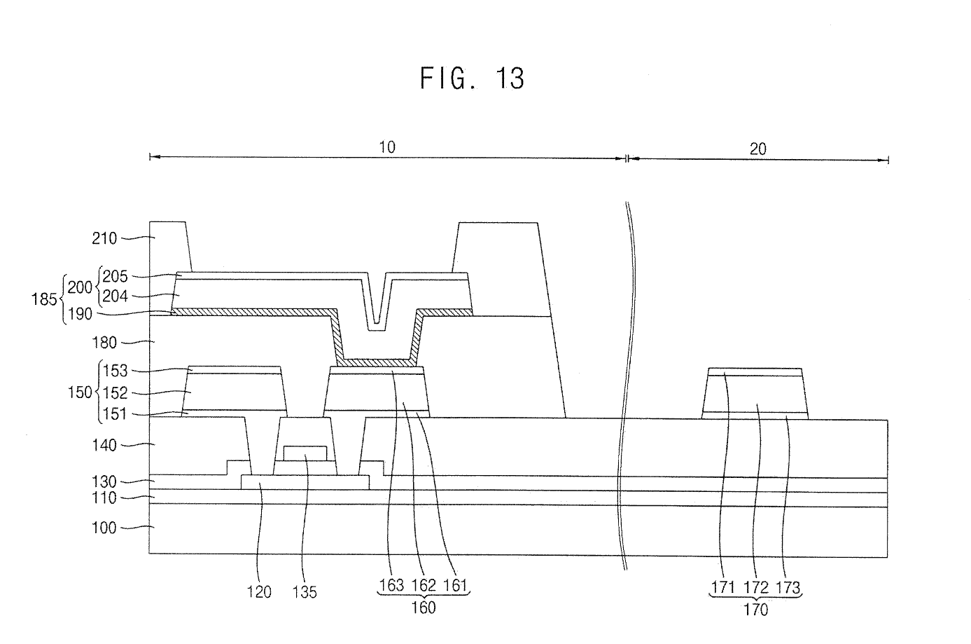

FIG. 13 illustrates a cross-sectional view of a backplane for a display device according to another exemplary embodiment. FIG. 13 may be a cross-sectional view cut along a line of the backplane for the display device in FIG. 2.

The backplane for the display device illustrated in FIG. 13 may have elements and/or constructions substantially the same as or similar to the backplane for the display device illustrated in FIG. 3 except for constructions of the second pixel electrode 200. Therefore, detailed descriptions on the repeated elements and/or constructions may be omitted, and like reference numerals are used to designate like elements.

In an exemplary embodiment, the second pixel electrode 200 may include a first layer 204 and a second layer 205 which are sequentially stacked. The first layer 204 of the second pixel electrode 200 may function as a main electrode layer. The first pixel electrode 190 and the second layer 205 of the second pixel electrode 200 may function as auxiliary electrode layers which protect a bottom surface and a top surface of the first layer 204 of the second pixel electrode 200, respectively. For example, the second pixel electrode 200 may be formed of a double-layered structure including silver (Ag)/indium-tin-oxide (ITO).

By way of summation and review, an organic light emitting display device may include a light emitting portion for displaying an image and a peripheral portion surrounding the light emitting portion. The peripheral portion may include a pad portion for transmitting signals to the light emitting portion. An organic light emitting element, which forms a pixel connected between a scan line and a data line as a matrix structure, may be formed in the light emitting portion. The organic light emitting element may include a pixel electrode, a common electrode, and an organic light emitting layer formed therebetween. A pad electrode for providing signals to the scan line and the data line may be formed in the pad portion.

When a pixel electrode layer is etched to form the pixel electrode, the exposed pad electrode and the pixel electrode layer adjacent to the pad electrode could cause or undergo a galvanic reaction in cooperation with or in response to exposure to an etchant (which is an electrolyte). The galvanic reaction refers to a phenomenon in which transition of electrons occurs by an oxidation/reduction reaction when two metals having different standard reduction potentials are connected by the electrolyte (e.g., both exposed to the electrolyte). The galvanic reaction could occur when a large difference in standard reduction potential between the materials in the pixel electrode layer and the pad electrode.

For example, if the pixel electrode layer were to include silver (Ag), and the pad electrode were to include aluminum (Al), the galvanic reaction could be generated when the two materials are in contact with an electrolyte because a difference in standard reduction potential between silver (Ag) and aluminum (Al) is relatively large. A silver ion (Ag+) may receive an electron from aluminum (Al) so that silver ion (Ag+) may be reduced to a silver particle (Ag). The silver particle (Ag) could move to the light emitting portion thereby inducing dark spots and decreasing the production yield.

The embodiments may provide a backplane for a display device including a pad electrode that may not be damaged during the formation of a pixel electrode.

The embodiments may provide a method of manufacturing a backplane for a display device during which damage of a pad electrode during the formation of a pixel electrode may be prevented.

The backplane for the display device according to exemplary embodiments may include the first pixel electrode with an etching characteristic different from that of the second pixel electrode, thereby including the pad electrode without a damage, e.g., protecting the pad electrode. In the method of manufacturing the backplane for the display device according to exemplary embodiments, the first pixel electrode layer may function as an etching prevention layer when the second pixel electrode layer is etched, thereby preventing a damage of the pad electrode.

The backplane for the display device according to exemplary embodiments may be applied to a display device included in a computer, a notebook, a mobile phone, a smartphone, a smart pad, a PMP, a PDA, an MP3 player, or the like.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A backplane for a display device having a light emitting portion and a pad portion, the backplane comprising:
a drain electrode in the light emitting portion on a substrate;
a pad electrode in the pad portion on the substrate;
a passivation layer in the light emitting portion to partially cover the drain electrode, the passivation layer exposing a portion of the drain electrode;
a first pixel electrode in the light emitting portion on the passivation layer and the exposed drain electrode; and
a second pixel electrode on the first pixel electrode,
wherein:
the second pixel electrode is formed of a material that is etchable by a first etching material, and
the first pixel electrode is formed of a material that is not etchable by the first etching material.

2. The backplane as claimed in claim 1, wherein:
the material of the first pixel electrode is etchable by a second etching material, and
the material of the second pixel electrode is not etchable by the second etching material.

3. The backplane as claimed in claim 1, wherein the second pixel electrode has a shape that conforms to a shape of the first pixel electrode.

4. The backplane as claimed in claim 1, wherein the pad electrode and the second pixel electrode include materials that are susceptible to undergoing a galvanic reaction in cooperation with an electrolyte.

5. The backplane as claimed in claim 1, wherein:
the pad electrode includes a first layer, a second layer, and a third layer which are sequentially stacked, and
the second layer of the pad electrode and the second pixel electrode include materials that are susceptible to undergoing a galvanic reaction in cooperation with an electrolyte.

6. The backplane as claimed in claim 5, wherein the first pixel electrode and the third layer of the pad electrode include a same material.

7. The backplane as claimed in claim 1, wherein:
the second pixel electrode includes a first layer, a second layer, and a third layer which are sequentially stacked, and
the first layer and the third layer protect a bottom surface and a top surface of the second layer, respectively.

8. The backplane as claimed in claim 1, wherein:
the second pixel electrode includes a first layer and a second layer which are sequentially stacked, and
the first pixel electrode and the second layer protect a bottom surface and a top surface of the first layer, respectively.

9. The backplane as claimed in claim 1, wherein the drain electrode and the pad electrode are disposed at a same level on the substrate.

10. A method of manufacturing a backplane for a display device having a light emitting portion and a pad portion, the method comprising:
forming a drain electrode on a substrate in the light emitting portion;
forming a pad electrode on the substrate in the pad portion;
forming a passivation layer in the light emitting portion to partially cover the drain electrode, the passivation layer exposing a portion of the drain electrode;
forming a first pixel electrode layer on the passivation layer, the exposed drain electrode, and the pad electrode;
forming a second pixel electrode layer on the first pixel electrode layer;
etching the second pixel electrode layer with a first etching material to form a second pixel electrode; and
etching the first pixel electrode layer with a second etching material to form a first pixel electrode,
wherein the first pixel electrode layer is not etched by the first etching material during the etching of the second pixel electrode layer.

11. The method as claimed in claim 10, wherein etching the second pixel electrode layer includes performing a wet-etching method.

12. The method as claimed in claim 10, wherein the second pixel electrode layer is not etched by the second etching material during the etching of the first pixel electrode layer.

13. The method as claimed in claim 12, wherein etching the first pixel electrode layer includes performing a dry-etching method.

14. The method as claimed in claim 10, wherein the pad electrode and the second pixel electrode layer include materials that are susceptible to undergoing a galvanic reaction in cooperation with an electrolyte.

15. The method as claimed in claim 14, wherein the first pixel electrode layer covers a top surface and a sidewall of the pad electrode.

16. The method as claimed in claim 10, wherein:
the pad electrode includes a first layer, a second layer, and a third layer which are sequentially stacked, and
the second layer of the pad electrode and the second pixel electrode layer include materials that are susceptible to undergoing a galvanic reaction in cooperation with an electrolyte.

17. The method as claimed in claim 16, wherein the first pixel electrode layer covers a sidewall of the pad electrode.

18. The method as claimed in claim 16, wherein the first pixel electrode layer and the third layer of the pad electrode include a same material.

19. The method as claimed in claim 10, wherein the drain electrode and the pad electrode are simultaneously formed.

20. The method as claimed in claim 10, further comprising:
forming a photoresist pattern corresponding to the second pixel electrode on the second pixel electrode layer prior to etching the second pixel electrode layer; and
removing the photoresist pattern after etching the first pixel electrode layer.
